(19) United States
(12) Patent Application Publication
(10) Pub. No.: US 2024/0146279 A1
(43) Pub. Date: May 2, 2024

(54) ACOUSTIC WAVE DEVICE

(71) Applicant: Murata Manufacturing Co., Ltd., Nagaokakyo-shi (JP)

(72) Inventor: Tetsuya KIMURA, Nagaokakyo-shi (JP)

(21) Appl. No.: 18/410,058

(22) Filed: Jan. 11, 2024

Related U.S. Application Data
(63) Continuation of application No. PCT/JP2022/025955, filed on Jun. 29, 2022.
(60) Provisional application No. 63/221,026, filed on Jul. 13, 2021.

(51) Int. Cl. H03H 9/02; H03H 9/13; H03H 9/17

(52) U.S. Cl. CPC H03H 9/02157; H03H 9/02031; H03H 9/0211; H03H 9/02228; H03H 9/131; H03H 9/132; H03H 9/173; H03H 9/174; H03H 9/176

(57) ABSTRACT

An acoustic wave device includes a support, a piezoelectric layer, and an IDT electrode. The IDT electrode includes first and second electrode fingers and first and second busbar electrodes. The first electrode finger extends in a second direction intersecting with a first direction. The second electrode finger extends in the second direction and faces a corresponding one of the first electrode finger in a third direction perpendicular to the second direction. A space in the support at least partially matches the IDT electrode from above in the first direction. The first or second electrode finger includes an underlying metal layer contacting the piezoelectric layer and a first metal layer on the underlying metal layer. The piezoelectric layer includes a diffusion layer where the piezoelectric layer contacts the underlying metal layer. The underlying metal layer and the diffusion layer include at least one of Ni, Cr, and Ti.

### CROSS REFERENCE TO RELATED APPLICATIONS

This application claims the benefit of priority to Provisional Application No. 63/221,026 filed on Jul. 13, 2021 and is a Continuation Application of PCT Application No. PCT/JP2022/025955 filed on Jun. 29, 2022. The entire contents of each application are hereby incorporated herein by reference.

### BACKGROUND OF THE INVENTION

### 1. Field of the Invention

The present disclosure relates to an acoustic wave device.

### 2. Description of the Related Art

Japanese Unexamined Patent Application Publication No. 2012-257019 discloses an acoustic wave device.

### SUMMARY OF THE INVENTION

It is desired that the bandwidth be wider in the acoustic wave device disclosed in Japanese Unexamined Patent Application Publication No. 2012-257019.

Example embodiments of the present invention increase the bandwidth.

An acoustic wave device according to an aspect of an example embodiment of the present invention includes a support, a piezoelectric layer, and an IDT electrode. The support has a thickness in a first direction and includes a support substrate. The piezoelectric layer is provided on the support. The IDT electrode is provided on a main surface of the piezoelectric layer and includes first and second electrode fingers and first and second busbar electrodes. The first electrode finger extends in a second direction that intersects with the first direction. The first electrode finger is connected to the first busbar electrode. The second electrode finger extends in the second direction and faces a corresponding one of the first electrode finger in a third direction which is perpendicular to the second direction. The second electrode finger is connected to the second busbar electrode. A space is included in the support at a position that at least partially corresponds to a position of the IDT electrode when the support is seen from above in the first direction. The first electrode finger or the second electrode finger includes an underlying metal layer and a first metal layer. The underlying metal layer contacts the piezoelectric layer. The first metal layer is stacked on the underlying metal layer. The underlying metal layer includes at least one of Ni, Cr, and Ti. The piezoelectric layer includes a diffusion layer at a position at which the piezoelectric layer contacts the underlying metal layer in the first direction. The diffusion layer includes at least one of Ni, Cr, and Ti.

According to example embodiments of the present disclosure, it is possible to increase the bandwidth.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view of an acoustic wave device according to a first example embodiment of the present invention.

FIG. 1B is a plan view of an electrode structure of the first example embodiment of the present invention.

FIG. 2 is a sectional view taken along line II-II in FIG. 1A.

FIG. 3A is a schematic sectional view for explaining a Lamb wave propagating through a piezoelectric layer in a comparative example.

FIG. 3B is a schematic sectional view for explaining a bulk wave of a thickness shear primary mode propagating through a piezoelectric layer in the first example embodiment of the present invention.

FIG. 4 is a schematic sectional view for explaining the amplitude direction of a bulk wave of the thickness shear primary mode propagating through the piezoelectric layer in the first example embodiment of the present invention.

FIG. 5 is a graph illustrating an example of the resonance characteristics of the acoustic wave device of the first example embodiment of the present invention.

FIG. 6 is a graph illustrating, regarding the acoustic wave device of the first example embodiment of the present invention, the relationship between d/2p, where d is the average thickness of the piezoelectric layer and p is the center-to-center distance or the average center-to-center distance between adjacent electrodes, and the fractional bandwidth of the acoustic wave device as a resonator.

FIG. 7 is a plan view illustrating an example in which a pair of electrodes is provided in the acoustic wave device of the first example embodiment of the present invention.

FIG. 8 is a reference graph illustrating an example of the resonance characteristics of the acoustic wave device of the first example embodiment of the present invention.

FIG. 9 is a diagram illustrating the relationship between the fractional bandwidth of many acoustic wave resonators formed based on the acoustic wave device of the first example embodiment of the present invention and the amount of phase shift of the impedance of a spurious response normalized at 180 degrees as the magnitude of the spurious response.

FIG. 10 is a graph illustrating the relationships between d/2p, the metallization ratio MR, and the fractional bandwidth.

FIG. 11 is a graph illustrating a map of the fractional bandwidth with respect to the Euler angles (0°, θ, ψ) of LiNbO₃ in a case in which d/p is approached as close to 0 as possible.

FIG. 12 is a partial cutaway perspective view for explaining an acoustic wave device according to an example embodiment of the present invention.

FIG. 13 is a sectional view illustrating a portion of the acoustic wave device according to the first example embodiment of the present invention.

FIG. 14 is a graph illustrating the resonant frequency with respect to the depth of a diffusion layer.

FIG. 15 is a graph illustrating the anti-resonant frequency with respect to the depth of the diffusion layer.

FIG. 16 is a graph illustrating the fractional bandwidth with respect to the depth of the diffusion layer.

FIG. 17 is a graph illustrating the fractional bandwidth with respect to td/tLN of an acoustic wave device according to a first example.

FIG. 18 is a graph illustrating the fractional bandwidth with respect to td/tLN of an acoustic wave device according to a second example.

FIG. 19 is a graph illustrating the fractional bandwidth with respect to td/tLN of an acoustic wave device according to a third example.

FIG. 20 is a graph illustrating the fractional bandwidth with respect to td/tLN of an acoustic wave device according to a fourth example.

FIG. 21 is a graph illustrating the fractional bandwidth with respect to td/tLN of an acoustic wave device according to a fifth example.

FIG. 22 is a graph illustrating td/tLN with respect to the thickness tLN of a piezoelectric layer.

### DETAILED DESCRIPTION OF THE EXAMPLE EMBODIMENTS

Example embodiments of the present disclosure will be described below in detail with reference to the drawings. The example embodiments are not provided to restrict the disclosure. The individual example embodiments described in the disclosure are only examples and the configurations discussed in different example embodiments may partially be replaced by or combined with each other. Regarding modified examples and second and subsequent example embodiments, reference will be given only to the configuration different from that of a first example embodiment while an explanation of the same configuration as the first example embodiment is being omitted. Similar advantages obtained by similar configurations are not repeated every time an example embodiment is explained.

### First Example Embodiment

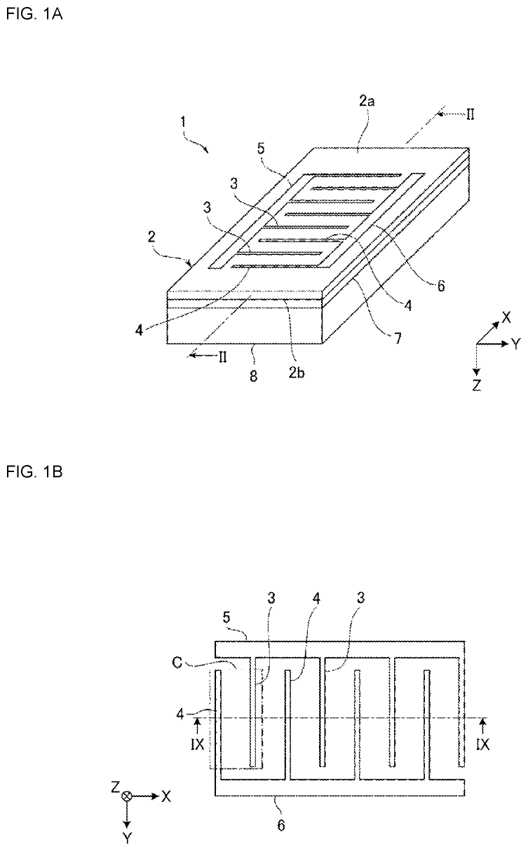

FIG. 1A is a perspective view of an acoustic wave device according to the first example embodiment. FIG. 1B is a plan view of the electrode structure of the first example embodiment.

An acoustic wave device 1 of the first example embodiment includes a piezoelectric layer 2 made of LiNbO₃, for example. The piezoelectric layer 2 may alternatively be made of LiTaO₃. The cut-angles of LiNbO₃ or LiTaO₃ in the first example embodiment are Z-cut, for example, but may be rotated Y-cut or X-cut. Preferably, the cut-angles of LiNbO₃ or LiTaO₃ are a propagation orientation of Y-propagation ±30° and X-propagation ±30°.

The thickness of the piezoelectric layer 2 is not restricted to a particular thickness, but it is preferably about 50 nm to about 1000 nm, for example, to effectively excite the thickness shear primary mode.

The piezoelectric layer 2 includes first and second main surfaces 2a and 2b facing each other in the Z direction. On the first main surface 2a, electrode fingers 3 and 4 are provided.

The electrode finger 3 is an example of a “first electrode finger”, while the electrode finger 4 is an example of a “second electrode finger”. In FIGS. 1A and 1B, the plural electrode fingers 3 are plural “first electrode fingers” connected to a first busbar electrode 5, while the plural electrode fingers 4 are plural “second electrode fingers” connected to a second busbar electrode 6. The plural electrode fingers 3 and the plural electrode fingers 4 are interdigitated each other. This defines an IDT (Interdigital Transducer) electrode including the electrode fingers 3 and 4 and the first and second busbar electrodes 5 and 6.

The electrode fingers 3 and 4 have a rectangular shape and have a longitudinal direction. An electrode finger 3 and an adjacent electrode finger 4 face each other in a direction perpendicular to this longitudinal direction. The longitudinal direction of the electrode fingers 3 and 4 and the direction perpendicular to the longitudinal direction of the electrode fingers 3 and 4 are both directions intersecting with the thickness direction of the piezoelectric layer 2. It can thus be said that an electrode finger 3 and an adjacent electrode finger 4 face each other in a direction intersecting with the thickness direction of the piezoelectric layer 2. In the following description, an explanation may be given such that the thickness direction of the piezoelectric layer 2 is the Z direction (or a first direction), the longitudinal direction of the electrode fingers 3 and 4 is the Y direction (or a second direction), and the direction perpendicular to the longitudinal direction of the electrode fingers 3 and 4 is the X direction (or a third direction).

The electrode fingers 3 and 4 may extend in a direction perpendicular to the longitudinal direction of the electrode fingers 3 and 4 shown in FIGS. 1A and 1B. That is, the electrode fingers 3 and 4 may extend in the extending direction of the first busbar electrode 5 and the second busbar electrode 6 shown in FIGS. 1A and 1B. In this case, the first busbar electrode 5 and the second busbar electrode 6 extend in the extending direction of the electrode fingers 3 and 4 shown in FIGS. 1A and 1B. Multiple pairs of electrode fingers 3 and electrode fingers 4, each pair being formed of an electrode finger 3, which is connected to one potential, and an electrode finger 4, which is connected to the other potential, adjacent to each other, are arranged in the direction perpendicular to the longitudinal direction of the electrode fingers 3 and 4.

“Electrode fingers 3 and 4 adjacent to each other” refers to, not that the electrode fingers 3 and 4 are disposed to directly contact each other, but that the electrode fingers 3 and 4 are disposed with a space therebetween. When electrode fingers 3 and 4 are adjacent to each other, an electrode connected to a hot electrode and an electrode connected to a ground electrode, including the other electrode fingers 3 and 4, are not disposed between the adjacent electrode fingers 3 and 4. The number of pairs of electrode fingers 3 and 4 is not necessarily an integral number and may be 1.5 or 2.5, for example.

The center-to-center distance, that is, the pitch, between the electrode fingers 3 and 4 is preferably about 1 μm to about 10 μm, for example. The center-to-center distance between the electrode fingers 3 and 4 is a distance from the center of the width of the electrode finger 3 in the direction perpendicular to the longitudinal direction of the electrode finger 3 to that of the electrode finger 4 in the direction perpendicular to the longitudinal direction of the electrode finger 4.

When at least one of the number of electrode fingers 3 and the number of electrode fingers 4 is plural (when 1.5 or more pairs of electrode fingers 3 and 4, each pair being formed by an electrode finger 3 and an electrode finger 4, are provided), the center-to-center distance between the electrode fingers 3 and 4 is the average value of that between adjacent electrode fingers 3 and 4 of the 1.5 or more pairs.

The width of each of the electrode fingers 3 and 4, that is, the dimension in the facing direction of the electrode fingers 3 and 4, is preferably about 150 nm to about 1000 nm, for example. The center-to-center distance between the electrode fingers 3 and 4 is a distance from the center of a dimension (width) of the electrode finger 3 in the direction perpendicular to the longitudinal direction of the electrode finger 3 to that of the electrode finger 4 in the direction perpendicular to the longitudinal direction of the electrode finger 4.

In the first example embodiment, since a Z-cut piezoelectric layer is used, the direction perpendicular to the longitudinal direction of the electrode fingers 3 and 4 is a direction perpendicular to the polarization direction of the piezoelectric layer 2. However, this is not the case if a piezoelectric layer of another cut angle is used as the piezoelectric layer 2. “Being perpendicular” does not necessarily mean being exactly perpendicular, but may mean being substantially perpendicular. For example, the angle between the direction perpendicular to the longitudinal direction of the electrode fingers 3 and 4 and the polarization direction may be in a range of about 90°±10°, for example.

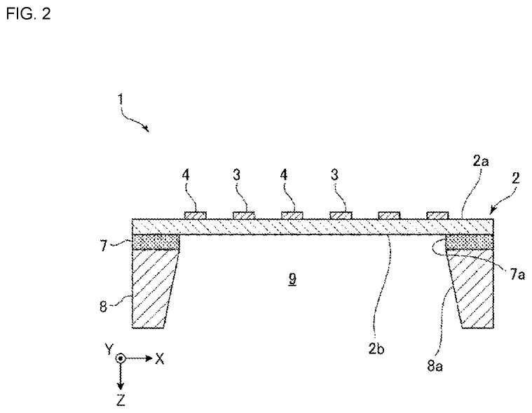

A support substrate 8 is stacked below the second main surface 2b of the piezoelectric layer 2 with an intermediate layer 7 interposed therebetween. The intermediate layer 7 and the support substrate 8 preferably are frame shaped and include cavities 7a and 8a, respectively, as shown in FIG. 2. With this structure, a space (air gap) 9 is provided.

The space 9 is provided not to interfere with the vibration of an excitation region C of the piezoelectric layer 2. Hence, the support substrate 8 is stacked below the second main surface 2b with the intermediate layer 7 therebetween and is located at a position at which the support substrate 8 does not overlap a region where at least one pair of electrode fingers 3 and 4 is disposed. The intermediate layer 7 may be omitted. The support substrate 8 can thus be stacked directly or indirectly below the second main surface 2b of the piezoelectric layer 2.

The intermediate layer 7 is made of silicon oxide, for example. Instead of silicon oxide, another suitable material, such as silicon nitride or alumina, may be used to form the intermediate layer 7.

The support substrate 8 is made of Si. The plane orientation of Si on the side of the piezoelectric layer 2 may be (100), (110), or (111). Preferably, high-resistivity Si, such as Si having a resistivity of about 4 kΩ or higher, for example, is used. A suitable insulating material or semiconductor material may be used for the support substrate 8. Examples of the material for the support substrate 8 are: piezoelectric materials, such as aluminum oxide, lithium tantalate, lithium niobate, and quartz; various ceramic materials, such as alumina, magnesia, sapphire, silicon nitride, aluminum nitride, silicon carbide, zirconia, cordierite, mullite, steatite, and forsterite; dielectric materials, such as diamond and glass; and semiconductor materials, such as gallium nitride.

The above-described plural electrode fingers 3 and 4 and first and second busbar electrodes 5 and 6 are made of a suitable metal or alloy, such as Al or an AlCu alloy. In the first example embodiment, the electrode fingers 3 and 4 and the first and second busbar electrodes 5 and 6 have a structure in which an Al film is stacked on a Ti film. A contact layer made of a material other than Ti may be used.

To drive the acoustic wave device 1, an AC voltage is applied to between the plural electrode fingers 3 and the plural electrode fingers 4. More specifically, an AC voltage is applied to between the first busbar electrode 5 and the second busbar electrode 6. With the application of the AC voltage, resonance characteristics based on a bulk wave of the thickness shear primary mode excited in the piezoelectric layer 2 can be exhibited.

In the acoustic wave device 1, d/p is set to about 0.5 or smaller, for example, where d is the thickness of the piezoelectric layer 2 and p is the center-to-center distance between adjacent electrode fingers 3 and 4 of one of multiple pairs of electrode fingers 3 and 4. This can effectively excite a bulk wave of the thickness shear primary mode and obtain high resonance characteristics. More preferably, d/p is about 0.24 or smaller, in which case, even higher resonance characteristics can be obtained.

As in the first example embodiment, when at least one of the number of electrode fingers 3 and the number of electrode fingers 4 is plural, that is, when 1.5 or more pairs of electrode fingers 3 and 4, each pair including an electrode finger 3 and an electrode finger 4, are provided, the center-to-center distance p between adjacent electrode fingers 3 and 4 is the average distance between adjacent electrode fingers 3 and 4 of the individual pairs.

The acoustic wave device 1 of the first example embodiment is configured as described above. Hence, even if the number of pairs of the electrode fingers 3 and 4 is reduced to miniaturize the acoustic wave device 1, the Q factor is unlikely to be decreased. This is because the acoustic wave device 1 is a resonator which does not require reflectors on both sides and only a small propagation loss is incurred. The reason why the acoustic wave device 1 does not require reflectors is that a bulk wave of the thickness shear primary mode is utilized.

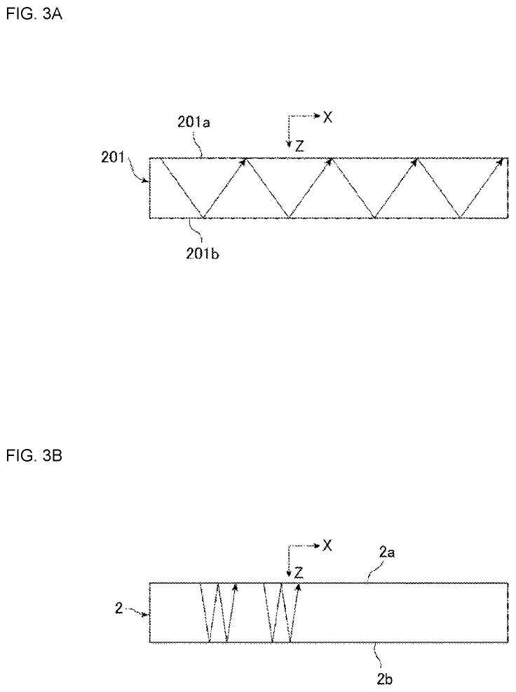

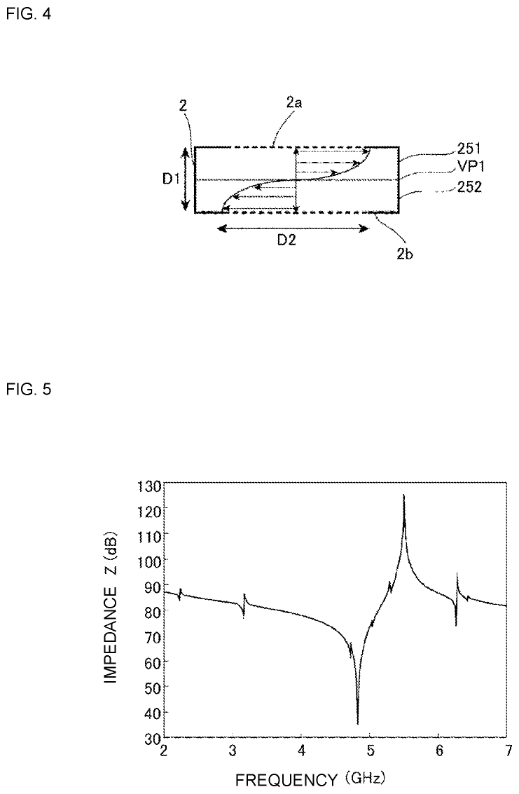

FIG. 3A is a schematic sectional view for explaining a Lamb wave propagating through a piezoelectric layer in a comparative example. FIG. 3B is a schematic sectional view for explaining a bulk wave of the thickness shear primary mode propagating through the piezoelectric layer in the first example embodiment. FIG. 4 is a schematic sectional view for explaining the amplitude direction of a bulk wave of the thickness shear primary mode propagating through the piezoelectric layer in the first example embodiment.

FIG. 3A shows a Lamb wave propagating through the piezoelectric layer in an acoustic wave device, such as that disclosed in Japanese Unexamined Patent Application Publication No. 2012-257019. As illustrated in FIG. 3A, a wave propagates through a piezoelectric layer 201 as indicated by the arrows. The piezoelectric layer 201 has a first main surface 201a and a second main surface 201b, and the thickness direction in which the first main surface 201a and the second main surface 201b are linked with each other is the Z direction. The X direction is a direction in which the electrode fingers 3 and 4 of an IDT electrode are arranged. As illustrated in FIG. 3A, a Lamb wave propagates in the X direction. Because of the characteristics of a Lamb wave, while the piezoelectric film 201 is entirely vibrated, the Lamb wave propagates in the X direction, and thus, reflectors are disposed on both sides to obtain resonance characteristics. Because of these characteristics, a propagation loss is incurred in the wave. If the size of the acoustic wave device is reduced, that is, if the number of pairs of electrode fingers is reduced, the Q factor is decreased.

In contrast, as illustrated in FIG. 3B, in the acoustic wave device of the first example embodiment, since the vibration displacement direction is the thickness shear direction, a wave propagates and resonates substantially in a direction in which the first main surface 2a and the second main surface 2b of the piezoelectric layer 2 are linked with each other, namely, substantially in the Z direction. That is, the X-direction components of the wave are much smaller than the Z-direction components. The resonance characteristics are obtained as a result of the wave propagating in the Z direction, and thus, the acoustic wave device does not require reflectors. Hence, a propagation loss, which would be caused by the propagation of a wave to reflectors, is not incurred. Even if the number of pairs of the electrode fingers 3 and 4 is reduced to miniaturize the acoustic wave device, the Q factor is unlikely to be decreased.

Regarding the amplitude direction of a bulk wave of the thickness shear primary mode, as shown in FIG. 4, the amplitude direction in a first region 251 included in the excitation region C (see FIG. 1B) of the piezoelectric layer 2, and that in a second region 252 included in the excitation region C, are opposite directions. In FIG. 4, a bulk wave generated when a voltage is applied to between the electrode fingers 3 and 4 so that the potential of the electrode finger 4 becomes higher than that of the electrode finger 3 is schematically illustrated. The first region 251, which is a portion of the excitation region C, is a region between a virtual plane VP1 and the first main surface 2a. The virtual plane VP1 is a plane which divides the piezoelectric layer 2 into two regions in a direction perpendicular to the thickness direction of the piezoelectric layer 2. The second region 252, which is a portion of the excitation region C, is a region between the virtual plane VP1 and the second main surface 2b.

As discussed above, in the acoustic wave device 1, at least one pair of electrode fingers 3 and 4 is disposed. Since a wave does not propagate through the piezoelectric layer 2 of the acoustic wave device 1 in the X direction, it is not essential that plural pairs of electrode fingers 3 and 4 are provided. That is, the provision of at least one pair of electrodes is sufficient.

In one example, the electrode finger 3 is an electrode connected to a hot potential, while the electrode finger 4 is an electrode connected to a ground potential. Conversely, the electrode finger 3 may be connected to a ground potential, while the electrode finger 4 may be connected to a hot potential. In the first example embodiment, as described above, at least one pair of electrodes is connected to a hot potential and a ground potential, and more specifically, one electrode of this pair is an electrode connected to a hot potential, and the other electrode is an electrode connected to a ground potential. No floating electrode is provided.

FIG. 5 is a graph illustrating an example of the resonance characteristics of the acoustic wave device of the first example embodiment. Example design parameters of the acoustic wave device 1 that has obtained the resonance characteristics shown in FIG. 5 are as follows.

Piezoelectric layer 2: LiNbO₃ having the Euler angles of (0°, 0°, 90°)
Thickness of piezoelectric layer 2: 400 nm
Length of excitation region C (see FIG. 1B): 40 μm
Number of pairs of electrode fingers 3 and 4: 21
Center-to-center distance (pitch) between electrode fingers 3 and 4: 3 μm
Width of electrode fingers 3 and 4: 500 nm d/p: 0.133
Intermediate layer 7: silicon oxide film having a thickness of 1 μm
Support substrate 8: Si

The excitation region C (see FIG. 1B) is a region where the electrode fingers 3 and 4 overlap each other as seen from the X direction perpendicular to the longitudinal direction of the electrode fingers 3 and 4. The length of the excitation region C is a dimension of the excitation region C in the longitudinal direction of the electrode fingers 3 and 4.

In the first example embodiment, the electrode-to-electrode distance of an electrode pair constituted by electrode fingers 3 and 4 was set to all equal among plural pairs. That is, the electrode fingers 3 and 4 were disposed at equal pitches.

As is seen from FIG. 5, despite that no reflectors are provided, high resonance characteristics having a fractional bandwidth of about 12.5% are obtained, for example.

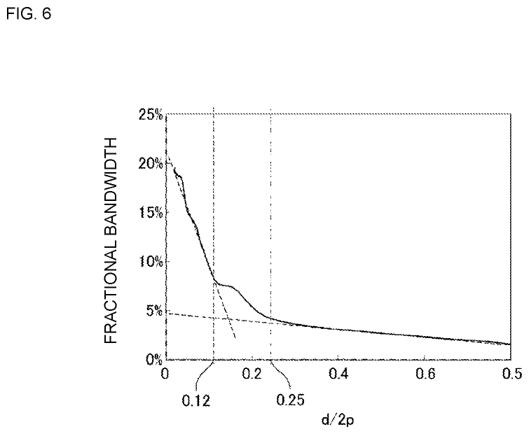

In the first example embodiment, as stated above, d/p is about 0.5 or smaller, and more preferably, d/p is about 0.24 or smaller, for example, where d is the thickness of the piezoelectric layer 2 and p is the center-to-center distance between the electrode fingers 3 and 4. This will be explained below with reference to FIG. 6.

Plural acoustic wave devices were made in a manner similar to the acoustic wave device which has obtained the resonance characteristics shown in FIG. 5, except that d/2pwas varied among these plural acoustic wave devices. FIG. 6 is a graph illustrating, regarding the acoustic wave device 1 of the first example embodiment, the relationship between d/2p, where d is the average thickness of the piezoelectric layer and p is the center-to-center distance or the average center-to-center distance between adjacent electrodes, and the fractional bandwidth of the acoustic wave device 1 as a resonator.

As is seen from FIG. 6, when d/2pexceeds about 0.25, that is, d/p>about 0.5, the fractional bandwidth remains less than about 5% even if d/p is changed. In contrast, when d/2p≤ about 0.25, that is, when d/p≤ about 0.5, the fractional bandwidth can be improved to about 5% or higher as long as d/p is changed in this range. It is thus possible to provide a resonator having a high coupling coefficient. When d/2pis about 0.12 or smaller, that is, when d/p is about 0.24 or smaller, the fractional bandwidth can be improved to about 7% or higher. Additionally, if d/p is adjusted in this range, a resonator having an even higher fractional bandwidth can be obtained. It is thus possible to provide a resonator having an even higher coupling coefficient. Hence, it has been validated that, as a result of setting d/p to about 0.5 or smaller, for example, a resonator utilizing a bulk wave of the thickness shear primary mode and exhibiting a high coupling coefficient can be provided.

As stated above, at least one pair of electrodes may be only one pair of electrodes. If one pair of electrodes is provided, the above-described center-to-center distance p is the center-to-center distance between the adjacent electrode fingers 3 and 4. If 1.5 or more pairs of electrodes are provided, the center-to-center distance p is the average distance between the adjacent electrode fingers 3 and 4 of the individual pairs.

Regarding the thickness d of the piezoelectric layer 2, if the piezoelectric layer 2 has variations in the thickness, the averaged thickness value may be used.

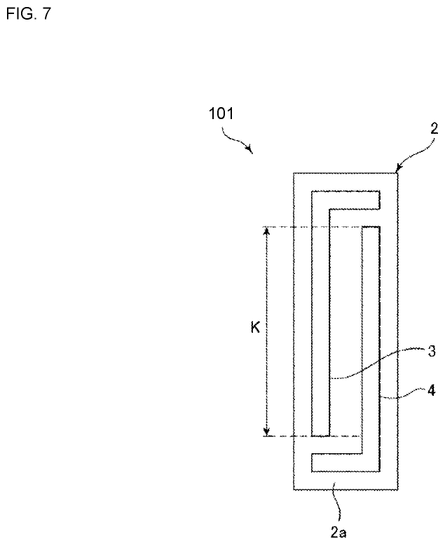

FIG. 7 is a plan view illustrating an example in which a pair of electrodes is provided in the acoustic wave device of the first example embodiment. In an acoustic wave device 101, a pair of electrodes including electrode fingers 3 and 4 is provided on the first main surface 2a of the piezoelectric layer 2. K in FIG. 7 indicates the overlapping width of the electrode fingers 3 and 4. As stated above, in the acoustic wave device of the present disclosure, only one pair of electrodes may be provided. Even in this case, a bulk wave of the thickness shear primary mode can be effectively excited if d/p is about 0.5 or smaller, for example.

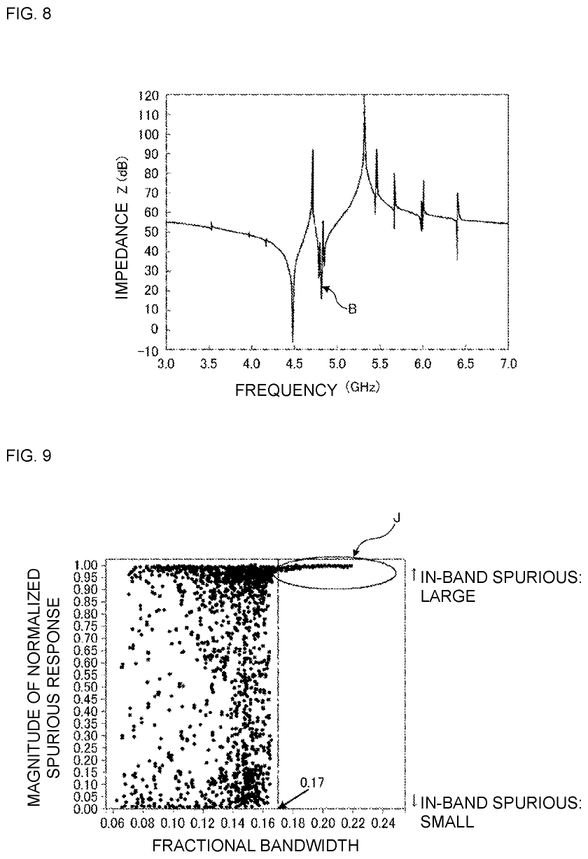

In the acoustic wave device 1, the metallization ratio MR of any one pair of adjacent electrode fingers 3 and 4 among the plural electrode fingers 3 and 4 to the excitation region C where this pair of electrode fingers 3 and 4 overlap each other as seen in their facing direction preferably satisfies MR≤about 1.75(d/p)+0.075. In this case, spurious responses can be effectively reduced. This will be explained below with reference to FIGS. 8 and 9.

FIG. 8 is a reference graph illustrating an example of the resonance characteristics of the acoustic wave device of the first example embodiment. The spurious response indicated by the arrow B is observed between the resonant frequency and the anti-resonant frequency. d/p was set to about 0.08, and the Euler angles of LiNbO₃ were set to (0°, 0°, 90°), for example. The metallization ratio MR was set to about 0.35, for example.

The metallization ratio MR will be explained below with reference to FIG. 1B. In the electrode structure in FIG. 1B, a pair of electrode fingers 3 and 4 will be focused, and it is assumed that only this pair is provided. In this case, the portion defined by the long dashed dotted lines is the excitation region C. The excitation region C is a region where the electrode finger 3 overlaps the electrode finger 4, a region where the electrode finger 4 overlaps the electrode finger 3, and a region where the electrode fingers 3 and 4 overlap each other in the region between the electrode fingers 3 and 4, when the electrode fingers 3 and 4 are seen in the direction perpendicular to the longitudinal direction thereof, that is, in the facing direction of the electrode fingers 3 and 4. The area of the electrode fingers 3 and 4 within the excitation region C to the area of the excitation region C is the metallization ratio MR. That is, the metallization ratio MR is a ratio of the area of a metallized portion to the area of the excitation region C.

If plural pairs of electrode fingers 3 and 4 are provided, the ratio of the areas of the metallized portions included in the total excitation region to the total area of the excitation region is used as the metallization ratio MR.

Many example acoustic wave resonators were formed based on the acoustic wave device of the first example embodiment. FIG. 9 is a diagram illustrating the relationship between the fractional bandwidth and the amount of phase shift of the impedance of a spurious response normalized at 180 degrees as the magnitude of a spurious response. The fractional bandwidth was adjusted by variously changing the film thickness of the piezoelectric layer 2 and the dimensions of electrode fingers 3 and 4. The results shown in FIG. 9 are obtained when a piezoelectric layer made of Z-cut LiNbO₃ was used. Similar results are also obtained if a piezoelectric layer having another cut-angle is used.

A spurious response is as high as about 1.0 in the region defined by the elliptical portion J in FIG. 9, for example. As is seen from FIG. 9, when the fractional bandwidth exceeds about 0.17, that is, about 17%, a large spurious response of about 1 or higher, for example, is observed within the pass band even if the parameters for the fractional bandwidth are changed. That is, as in the resonance characteristics in FIG. 8, a large spurious response indicated by the arrow B is observed within the pass band. Accordingly, the fractional bandwidth is preferably about 17% or lower, for example. In this case, the spurious response can be reduced by the adjustment of the film thickness of the piezoelectric layer 2 and the dimensions of electrode fingers 3 and 4, for example.

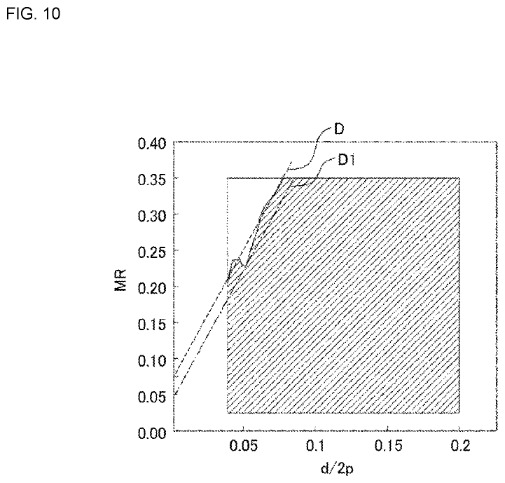

FIG. 10 is a graph illustrating the relationships between d/2p, the metallization ratio MR, and the fractional bandwidth. Based on the acoustic wave device 1 of the first example embodiment, various acoustic wave devices 1 were made by changing d/2p and MR. Then, the fractional bandwidth was measured. The hatched portion on the right side of the broken line D in FIG. 10 is a region where the fractional bandwidth is about 17% or lower, for example. The boundary between the hatched portion and a portion without can be expressed by MR=about 3.5(d/2p)+0.075, that is, MR=about 1.75(d/p)+0.075, for example. Preferably, MR≤about 1.75(d/p)+0.075, in which case, the fractional bandwidth is likely to be about 17% or lower, for example. More preferably, the region where the fractional bandwidth is about 17% or lower is the region on the right side of the boundary expressed by MR=about 3.5(d/2p)+0.05, which is indicated by the long dashed dotted line D1 in FIG. 10. That is, if MR≤about 1.75(d/p)+0.05, the fractional bandwidth can reliably be about 17% or lower, for example.

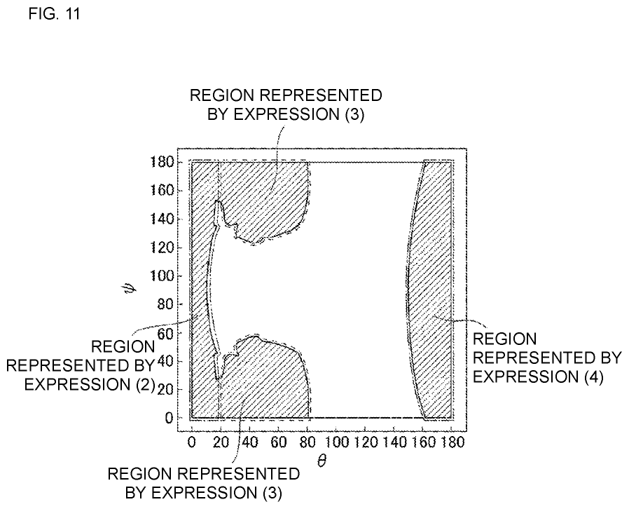

FIG. 11 is a graph illustrating a map of the fractional bandwidth with respect to the Euler angles (0°, θ, ψ) of LiNbO₃ in a case in which d/p is approached as close to 0 as possible. The hatched portions in FIG. 11 are regions where a fractional bandwidth of at least about 5% or higher is obtained. Example ranges of the regions can be approximated to the ranges represented by the following expressions (2), (3), and (4).

(0°±10°,0° to 20°,a desirable angle of ψ) Expression (2)

(0°±10°, 20° to 80°, 0° to 60° (1−(θ−50)²/900)^{1/2}) or (0°±10°,20° to 80°, [180°−60° (1−(θ−50)²/900)^{1/2}] to 180°) Expression (3)

(0°±10°, [180°−30°(1−(ψ−90)²/8100)¹²] to 180°, a desirable angle of ψ) Expression (4)

When the Euler angles are in the range represented by the above-described expression (2), (3), or (4), a sufficiently wide fractional bandwidth can be obtained, which is desirable.

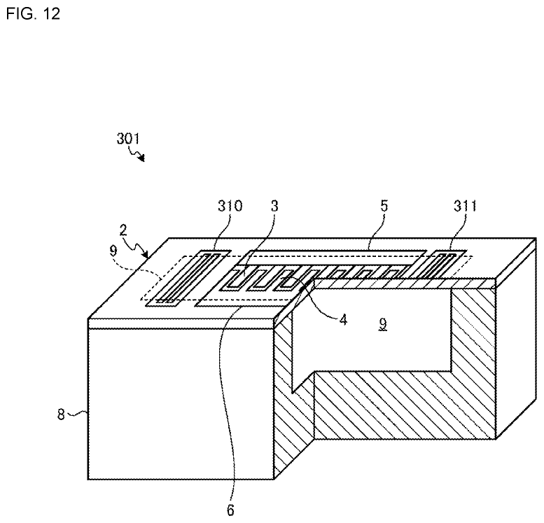

FIG. 12 is a partial cutaway perspective view for explaining an acoustic wave device according to an example embodiment of the present disclosure. In FIG. 12, the outer peripheral edges of a space 9 are indicated by the broken lines. An acoustic wave device of the present disclosure may be an acoustic wave device utilizing a Lamb wave. In this case, as shown in FIG. 12, an acoustic wave device 301 includes reflectors 310 and 311. The reflector 310 is disposed on one side of the electrode fingers 3 and 4 on the piezoelectric layer 2 in the acoustic-wave propagating direction, while the reflector 311 is disposed on the other side of the electrode fingers 3 and 4 in the acoustic-wave propagating direction. In the acoustic wave device 301, a Lamb wave is excited with the application of an AC electric field to the electrode fingers 3 and 4 disposed above the space 9. Since the reflectors 310 and 311 are disposed on both sides of the electrode fingers 3 and 4, resonance characteristics based on the Lamb wave can be obtained.

As described above, in the acoustic wave devices 1 and 101, a bulk wave of the thickness shear primary mode is utilized. In the acoustic wave devices 1 and 101, the first and second electrode fingers 3 and 4 are adjacent electrodes, and d/p is set to about 0.5 or smaller, for example, where d is the thickness of the piezoelectric layer 2 and p is the center-to-center distance between the first and second electrode fingers 3 and 4. With this configuration, even if the acoustic wave device is reduced in size, the Q factor can be improved.

In the acoustic wave devices 1 and 101, the piezoelectric layer 2 is made of lithium niobate or lithium tantalate. On the first main surface 2a or the second main surface 2b of the piezoelectric layer 2, the first and second electrode fingers 3 and 4 facing each other in the direction interesting with the thickness direction of the piezoelectric layer 2 are disposed. It is desirable that a protection film cover the first and second electrode fingers 3 and 4.

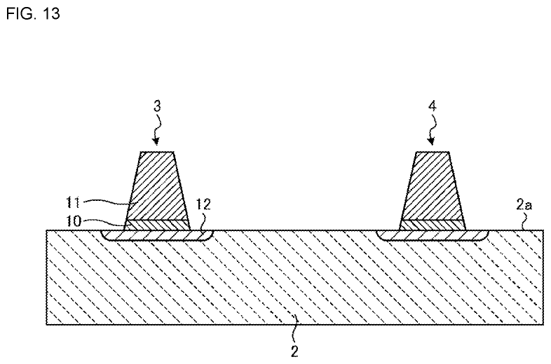

FIG. 13 is a sectional view illustrating a portion of the acoustic wave device according to the first example embodiment. More specifically, FIG. 13 is a sectional view only illustrating a portion of the piezoelectric layer 2, one electrode finger 3, and one electrode finger 4 of the acoustic wave device of the first example embodiment. In the following description, an explanation may be given such that, regarding directions parallel with the Z direction, one direction is the upward direction and the other direction is the downward direction. In the acoustic wave device of the first example embodiment, the piezoelectric layer 2 is disposed on a support, which is not shown. The support includes the support substrate 8. The support may also include the intermediate layer 7 on the support substrate 8.

As illustrated in FIG. 13, the first electrode finger 13 or the second electrode finger 14 includes an underlying metal layer 10 and a first metal layer 11. The underlying metal layer 10 contacts the piezoelectric layer 2. In the example in FIG. 13, the underlying metal layer 10 contacts the first main surface 2a of the piezoelectric layer 2. The underlying metal layer 10 includes at least one of Ni, Cr, and Ti. The underlying metal layer 10 is made of Ni, Cr, or Ti, for example, but is not limited to an elemental metal and may be an alloy, such as nichrome. The first metal layer 11 is a metal layer stacked on the underlying metal layer 10. That is, the underlying metal layer 10 is disposed between the piezoelectric layer 2 and the first metal layer 11 in the Z direction. The material for the first metal layer 11 is not limited to a particular material and may be made of a suitable metal or alloy, such as Al or an AlCu alloy.

As illustrated in FIG. 13, the piezoelectric layer 2 includes a diffusion layer 12. The diffusion layer 12 is a layer created as a result of a component of the underlying metal layer 10 being diffused into a portion of the piezoelectric layer 2 contacting the underlying metal layer 10 in the Z direction due to heat generated during manufacturing or operation. As shown in FIG. 13, the diffusion layer 12 is located at a position at which it contacts the underlying metal layer 10 in the Z direction. In the example in FIG. 13, the diffusion layer 12 is located at a position at which it contacts the underlying metal layer 10 on the side of the first main surface 2a of the piezoelectric layer 2. The diffusion layer 12 includes at least one of Ni, Cr, and Ti, which is a component of the underlying metal layer 10. That is, the diffusion layer 12 is made of a mixture of a component of the piezoelectric layer 2 and a component of the underlying metal layer 10. In other words, it can be said that the diffusion layer 12 is a portion of the piezoelectric layer 2 including at least one of Ni, Cr, and Ti. With this configuration, the bandwidth can become wider than that when the piezoelectric layer 2 does not include the diffusion layer 12.

In the following description, an explanation may be given such that the longest dimension in the diffusion layer 12 in the Z direction is the depth of the diffusion layer 12. The depth of the diffusion layer 12 can be measured by examining a cross section of the acoustic wave device, which includes a cross section of the electrode finger and which is parallel with the Z direction, with a TEM (Transmission Electron Microscope). The measurement method for the depth of the diffusion layer 12 is not restricted to this method. EDX (Energy Dispersive X-ray Spectrometry) or Raman spectroscopy may be used to measure the depth of the diffusion layer 12. In this case, in a cross section of the acoustic wave device which includes a cross section of the electrode finger and which is parallel with the Z direction, the Z-direction longest dimension of a region of the piezoelectric layer 2 including at least one of Ni, Cr, and Ti may be assumed as the depth of the diffusion layer 12.

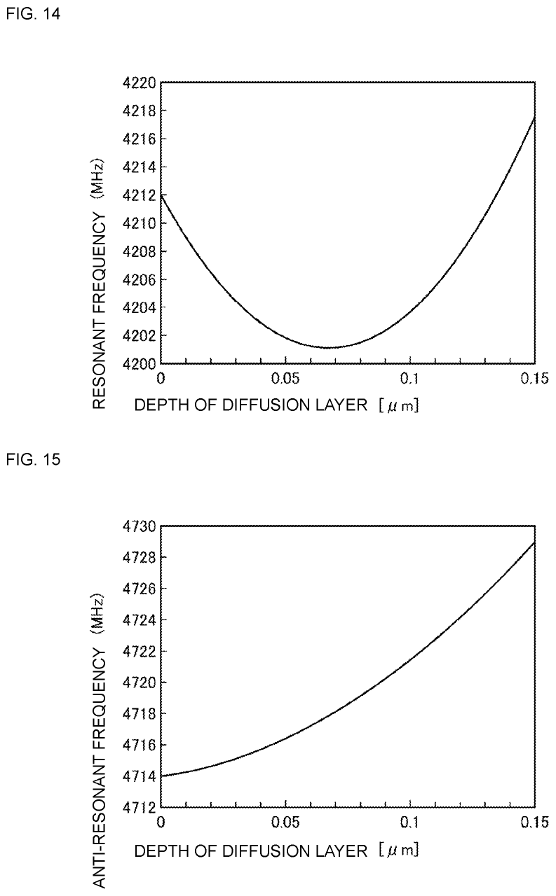

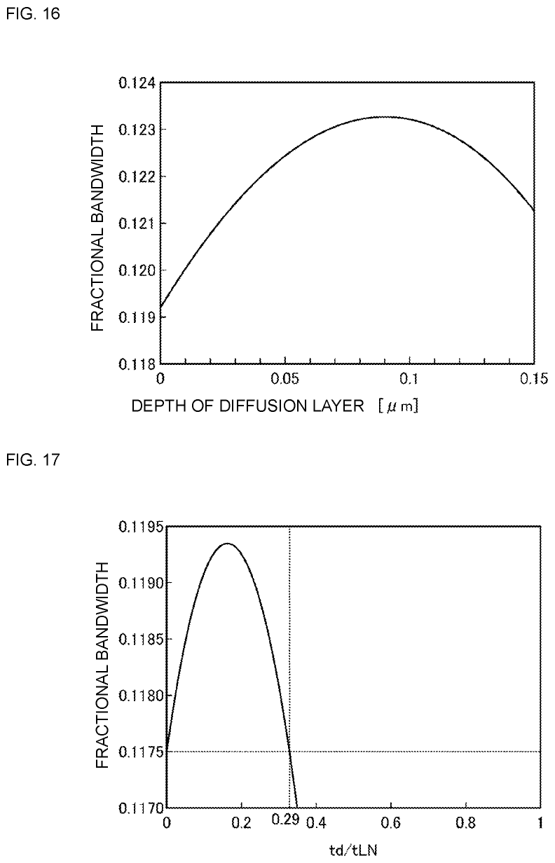

FIG. 14 is a graph illustrating the resonant frequency with respect to the depth of the diffusion layer. FIG. 15 is a graph illustrating the anti-resonant frequency with respect to the depth of the diffusion layer. FIG. 16 is a graph illustrating the fractional bandwidth with respect to the depth of the diffusion layer. As shown in FIG. 14, when the depth of the diffusion layer 12 becomes about 0.065 μm or greater, the resonant frequency stops decreasing and starts to rise. As shown in FIG. 15, the anti-resonant frequency becomes higher as the depth of the diffusion layer 12 becomes larger. Accordingly, as shown in FIG. 16, by setting the depth of the diffusion layer 12 to be larger than 0 μm, the fractional bandwidth can become wider than that when the depth of the diffusion layer 12 is 0 μm. The provision of the diffusion layer 12 in the piezoelectric layer 2 can thus make the bandwidth wider than when the piezoelectric layer 2 does not include the diffusion layer 12.

Examples will be discussed below. As examples of the acoustic wave device of the first example embodiment, simulation models of acoustic wave devices according to first through fifth examples were made with the following design parameters. The thicknesses of the piezoelectric layers 2 in the first through fifth examples were made different from each other. In the simulations, the fractional bandwidths were calculated, assuming that the material (Ti) for the underlying metal layer 10 was isotropically diffused into the piezoelectric layer 2. In the acoustic wave devices of the first through fifth examples, a protection film was provided on the piezoelectric layer 2 and the electrode fingers 3 and 4.
Piezoelectric layer 2: LiNbO₃ having the Euler angles of (0°, 0°, 90°)
First metal layer 11: Al
Thickness of first metal layer 11: 500 nm
Center-to-center distance between electrode fingers 3 and 4: 4.16 μm
Underlying metal layer 10: Ti
Thickness of underlying metal layer 10: 10 nm
Protection film: SiO₂
Thickness of protection film: 133 nm

FIG. 17 is a graph illustrating the fractional bandwidth with respect to td/tLN in the acoustic wave device according to the first example. In FIG. 17, td/tLN is a value obtained by dividing the depth td of the diffusion layer 12 by the thickness of tLN of the piezoelectric layer 2. In the first example, the thickness tLN of the piezoelectric layer 2 was set to 300 nm. As is seen from FIG. 17, in the first example, when td/tLN is about 0.29 or smaller, the fractional bandwidth can become wider than that when td/tLN is 0, for example.

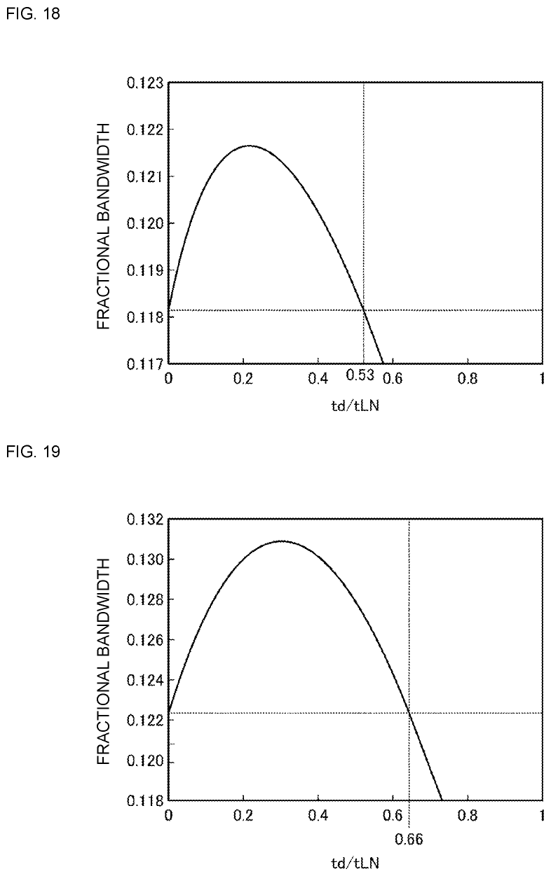

FIG. 18 is a graph illustrating the fractional bandwidth with respect to td/tLN in the acoustic wave device according to the second example. In the second example, the thickness tLN of the piezoelectric layer 2 was set to about 400 nm, for example. As is seen from FIG. 18, in the second example, when td/tLN is about 0.53 or smaller, the fractional bandwidth can become wider than that when td/tLN is 0, for example.

FIG. 19 is a graph illustrating the fractional bandwidth with respect to td/tLN in the acoustic wave device according to the third example. In the third example, the thickness tLN of the piezoelectric layer 2 was set to about 500 nm, for example. As is seen from FIG. 19, in the third example, when td/tLN is about 0.66 or smaller, the fractional bandwidth can become wider than that when td/tLN is 0, for example.

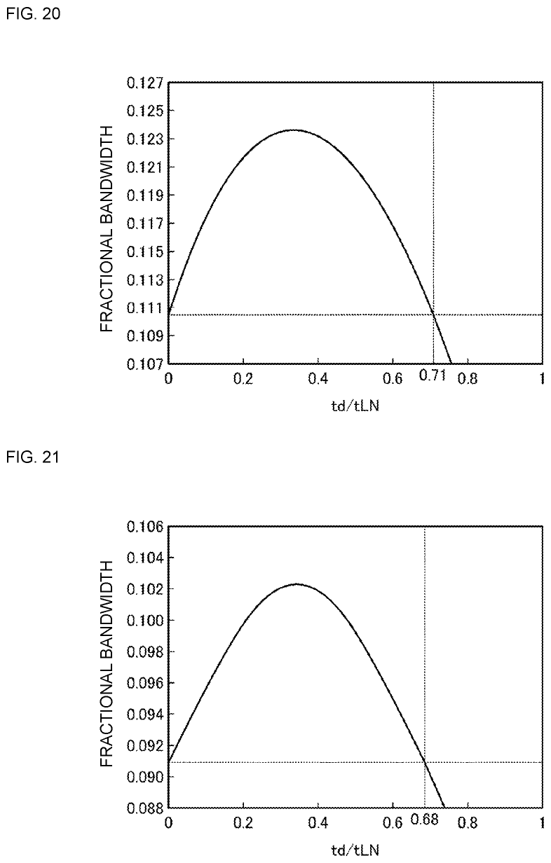

FIG. 20 is a graph illustrating the fractional bandwidth with respect to td/tLN in the acoustic wave device according to the fourth example. In the fourth example, the thickness tLN of the piezoelectric layer 2 was set to about 600 nm, for example. As is seen from FIG. 20, in the fourth example, when td/tLN is about 0.71 or smaller, the fractional bandwidth can become wider than that when td/tLN is 0, for example.

FIG. 21 is a graph illustrating the fractional bandwidth with respect to td/tLN in the acoustic wave device according to the fifth example. In the fifth example, the thickness tLN of the piezoelectric layer 2 was set to about 700 nm, for example. As is seen from FIG. 21, in the fifth example, when td/tLN is about 0.68 or smaller, the fractional bandwidth can become wider than that when td/tLN is 0, for example.

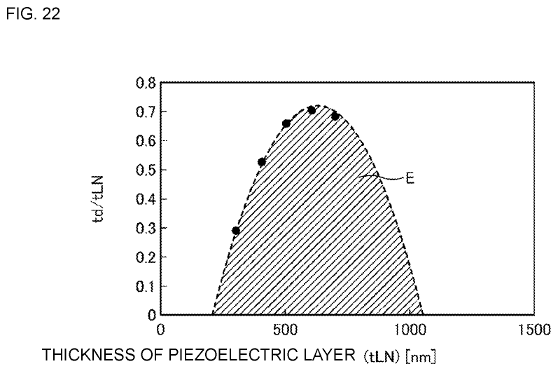

FIG. 22 is a graph illustrating td/tLN with respect to the thickness tLN of the piezoelectric layer. In FIG. 22, the upper maximum values in the ranges of td/tLN that can make the fractional bandwidth wider in the first through fifth examples are plotted. As illustrated in FIG. 22, the results of the first through fifth examples show that the fractional bandwidth can be increased in the region E indicated by the hatched portion in FIG. 22. Hence, setting the thickness tLN of the piezoelectric layer to about 100 nm to about 1000 nm, for example, can reliably increase the fractional bandwidth, thus achieving a wider bandwidth with high reliability. The range of the region E is approximated to a range represented by expression (1). When the depth td of the diffusion layer 12 and the thickness tLN of the piezoelectric layer 2 satisfy expression (1), the fractional bandwidth can reliably become wider than that when the diffusion layer 12 is not provided, thus increasing the bandwidth with high reliability.

td/tLN<−4×10⁻⁶×(tLN)²+5.02×10⁻³×tLN−0.85 (1)

As described above, the acoustic wave device according to the first example embodiment includes a support, a piezoelectric layer 2, and an IDT electrode. The support has a thickness in a first direction and includes a support substrate 8. The piezoelectric layer 2 is provided on the support. The IDT electrode is provided on a main surface (first main surface 2a) of the piezoelectric layer 2 and includes first and second electrode fingers 3 and 4 and first and second busbar electrodes 5 and 6. The first electrode fingers 3 extend in a second direction which intersects with the first direction. The first electrode fingers 3 are connected to the first busbar electrode 5. The second electrode fingers 4 extend in the second direction and face the corresponding first electrode fingers 3 in a third direction which is perpendicular to the second direction. The second electrode fingers 4 are connected to the second busbar electrode 6. A space 9 is included in the support at a position that at least partially corresponds to a position of the IDT electrode when the support is seen from above in the first direction. The first electrode finger 3 or the second electrode finger 4 includes an underlying metal layer 10 and a first metal layer 11. The underlying metal layer 10 contacts the main surface of the piezoelectric layer 2. The first metal layer 11 is stacked on the underlying metal layer 10. The underlying metal layer 10 includes at least one of Ni, Cr, and Ti. The piezoelectric layer 2 includes a diffusion layer 12 at a position at which the piezoelectric layer 2 contacts the underlying metal layer 10 in the first direction. The diffusion layer 12 includes at least one of Ni, Cr, and Ti. With this configuration, the bandwidth can be increased.

In a desirable mode, when the value obtained by dividing the depth td[nm] of the diffusion layer 12 by the thickness tLN[nm] of the piezoelectric layer 2 is represented by td/tLN, the depth td[nm] of the diffusion layer 12 and the thickness tLN[nm] of the piezoelectric layer 2 satisfy the following expression (1). This can reliably increase the bandwidth.

td/tLN<−4×10⁻⁶×(tLN)²+5.02×10⁻³×tLN−0.85 (1)

In a desirable mode, the thickness of the piezoelectric layer 2 is about 100 nm to about 1000 nm, for example. This can reliably increase the bandwidth.

In a desirable mode, the thickness of the piezoelectric layer 2 is about 2p or smaller, where p is the center-to-center distance between adjacent first and second electrode fingers 3 and 4 among the first and second electrode fingers 3 and 4. With this configuration, the acoustic wave device 1 can be reduced in size and the Q factor can be improved.

In a desirable mode, the piezoelectric layer 2 includes lithium niobate or lithium tantalate. It is thus possible to provide an acoustic wave device that can exhibit high resonance characteristics.

In a desirable mode, the acoustic wave device is structured to generate a bulk wave of the thickness shear mode. It is thus possible to provide an acoustic wave device that exhibits high resonance characteristics with an increased coupling coefficient.

In a desirable mode, d/p≤ about 0.5 is satisfied, for example, where d is the thickness of the piezoelectric layer 2 and p is the center-to-center distance between adjacent first and second electrode fingers 3 and 4. With this configuration, the acoustic wave device 1 can be reduced in size and the Q factor can be improved.

In a more desirable mode, d/p is about 0.24 or smaller, for example. With this configuration, the acoustic wave device 1 can be reduced in size and the Q factor can be improved.

In a desirable mode, a region in which the first and second electrode fingers 3 and 4 overlap each other as seen in the third direction is an excitation region C, and MR≤about 1.75(d/p)+0.075 is satisfied, for example, where MR is a metallization ratio of the first and second electrode fingers 3 and 4 to the excitation region C. In this case, the fractional bandwidth can reliably become about 17% or lower, for example.

In a desirable mode, the acoustic wave device is structured to generate a Lamb wave. It is thus possible to provide an acoustic wave device that can exhibit high resonance characteristics.

In a desirable mode, the Euler angles (p, θ, ψ) of lithium niobate or lithium tantalate are in a range represented by expression (2), (3), or (4). In this case, the fractional bandwidth can sufficiently be increased.

(0°±10°, 0° to 20°, a desirable angle of ψ) Expression (2)

(0°±10°, 20° to 80°, 0° to 60° (1−(θ−50)²/900)^{1/2}) or(0°±10°,20° to 80°, [180°−60° (1−(θ−50)²/900)^{1/2}] to 180°) Expression (3)

(0°±10°, [180°−30° (1−(ψ−90)²/8100)^{1/2}] to 180°, a desirable angle of ψ) Expression (4)

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support with a thickness in a first direction and including a support substrate;
a piezoelectric layer provided on the support; and
an IDT electrode provided on a main surface of the piezoelectric layer and including first and second electrode fingers and first and second busbar electrodes, the first electrode finger extending in a second direction which intersects with the first direction, the first electrode finger being connected to the first busbar electrode, the second electrode finger extending in the second direction and facing a corresponding one of the first electrode finger in a third direction which is perpendicular to the second direction, the second electrode finger being connected to the second busbar electrode; wherein
a space is included in the support at a position that at least partially corresponds to a position of the IDT electrode when the support is seen from above in the first direction;
the first electrode finger or the second electrode finger includes an underlying metal layer and a first metal layer, the underlying metal layer contacting the piezoelectric layer, the first metal layer being stacked above the underlying metal layer;
the underlying metal layer includes at least one of Ni, Cr, and Ti; and
the piezoelectric layer includes a diffusion layer at a position at which the piezoelectric layer contacts the underlying metal layer in the first direction, the diffusion layer including at least one of Ni, Cr, and Ti.

2. The acoustic wave device according to claim 1, wherein a depth td[nm] of the diffusion layer and a thickness tLN[nm] of the piezoelectric layer satisfy an expression:
td/tLN<−4×10⁻⁶×(tLN)²+5.02×10⁻³×tLN−0.85
where td/tLN is a value obtained by dividing the depth td[nm] of the diffusion layer by the thickness tLN[nm] of the piezoelectric layer.

3. The acoustic wave device according to claim 1, wherein a thickness of the piezoelectric layer is about 100 nm to about 1000 nm.

4. The acoustic wave device according to claim 1, wherein a thickness of the piezoelectric layer is about 2p or smaller, where p is a center-to-center distance between adjacent first and second electrode fingers of the first and second electrode fingers.

5. The acoustic wave device according to claim 1, wherein the piezoelectric layer includes lithium niobate or lithium tantalate.

6. The acoustic wave device according to claim 5, wherein the acoustic wave device is structured to generate a bulk wave of a thickness shear mode.

7. The acoustic wave device according to claim 6, wherein d/p≤ about 0.5 is satisfied, where d is a thickness of the piezoelectric layer and p is a center-to-center distance between adjacent first and second electrode fingers.

8. The acoustic wave device according to claim 7, wherein the d/p is about 0.24 or smaller.

9. The acoustic wave device according to claim 1, wherein
a region in which the first and second electrode fingers overlap each other as seen in the third direction is an excitation region; and
MR≤about 1.75(d/p)+0.075 is satisfied, where MR is a metallization ratio of the first and second electrode fingers to the excitation region.

10. The acoustic wave device according to claim 1, wherein the acoustic wave device is structured to generate a Lamb wave.

11. The acoustic wave device according to claim 5, wherein Euler angles (φ, θ, ψ) of the lithium niobate or the lithium tantalate are in a range represented by one of the following expressions:
(0°±10°, 0° to 20°, a desirable angle of ψ)
(0°±10°, 20° to 80°, 0° to 60° (1−(θ−50)²/900)^{1/2}) or(0°±10°, 20° to 80°, [180°−60° (1−(θ−50)²/900)^{1/2}] to 180°)
(0°±10°, [180°−30° (1−(ψ−90)²/8100)^{1/2}] to 180°, a desirable angle of ψ).

12. The acoustic wave device according to claim 1, wherein a width of each of the first and second electrode fingers is about 150 nm to about 1000 nm.

13. The acoustic wave device according to claim 1, wherein an angle between a direction perpendicular to a longitudinal direction of the first and second electrode fingers and a polarization direction is in a range of about 90°±10°.

14. The acoustic wave device according to claim 1, wherein the support includes an intermediate layer between the support substrate and the piezoelectric layer.

15. The acoustic wave device according to claim 14, wherein the support substrate and the intermediate layer are frame-shaped and include cavities defining the space.

16. The acoustic wave device according to claim 14, wherein the intermediate layer includes one of silicon oxide, silicon nitride, or alumina.

17. The acoustic wave device according to claim 14, wherein the support substrate is made of Si.

18. The acoustic wave device according to claim 14, wherein the support substrate is made of one of a high-resistivity material, an insulating material, a semiconductor material, or a piezoelectric material.

19. The acoustic wave device according to claim 14, wherein the support substrate is made of one of aluminum oxide, lithium tantalate, lithium niobate, quartz, alumina, magnesia, sapphire, silicon nitride, aluminum nitride, silicon carbide, zirconia, cordierite, mullite, steatite, forsterite, diamond, glass, or gallium nitride.

20. The acoustic wave device according to claim 1, further comprising reflectors on both sides of the first and second electrode fingers.
